(19) United States
(12) Patent Application Publication
(10) Pub. No.: US 2025/0105014 A1
(43) Pub. Date: Mar. 27, 2025

(54) ETCHING METHOD

(71) Applicant: KABUSHIKI KAISHA TOSHIBA, Tokyo (JP)

(72) Inventors: Hiroki KAWAKAMI, Yokohama (JP); Kazuhito HIGUCHI, Yokohama (JP); Susumu OBATA, Yokohama (JP); Takayuki TAJIMA, Sagamihara (JP)

(73) Assignee: KABUSHIKI KAISHA TOSHIBA, Tokyo (JP)

(21) Appl. No.: 18/602,237

(22) Filed: Mar. 12, 2024

(30) Foreign Application Priority Data
Sep. 21, 2023 (JP) 2023-155508

(51) Int. Cl. H01L 21/306

(52) U.S. Cl. CPC H01L 21/30604

(57) ABSTRACT

According to one embodiment, an etching method is provided. The etching method includes: forming a layer containing a first metal catalyst at a surface containing a semiconductor; first etching using the first metal catalyst; forming a layer containing a second metal catalyst having a larger diffusion coefficient than that of the first metal catalyst at the layer containing the first metal catalyst; and second etching using the second metal catalyst.

### CROSS-REFERENCE TO RELATED APPLICATIONS

This application is based upon and claims the benefit of priority from Japanese Patent Application No. 2023-155508, filed Sep. 21, 2023, the entire contents of which are incorporated herein by reference.

### FIELD

Embodiments described herein relate generally to an etching method.

### BACKGROUND

Etching is known as a method for forming a hole or a groove in a substrate such as a semiconductor wafer. Examples of the etching include a metal-assisted etching (also called metal-assisted chemical etching (MacEtch)) method. The metal-assisted etching (MacEtch) method is, for example, an etching method using a noble metal or the like as a catalyst. In a case where a trench having a high aspect ratio is processed in a substrate containing Si by this method, a processing defect such as porous Si occurs near an upper end portion of the side wall defining the trench.

### BRIEF DESCRIPTION OF THE DRAWINGS

FIG. 1 is a flowchart illustrating a flow of steps included in an etching method according to an embodiment.

FIG. 2 is a cross-sectional view schematically illustrating a structure obtained by forming a first metal catalyst in the method of the embodiment.

FIG. 3 is a cross-sectional view schematically illustrating a structure obtained by first etching in the method of the embodiment.

FIG. 4 is a cross-sectional view schematically illustrating a structure obtained by forming a second metal catalyst in the method of the embodiment.

FIG. 5 is a cross-sectional view schematically illustrating a structure obtained by second etching in the method of the embodiment.

FIG. 6 is a cross-sectional view schematically illustrating a structure obtained by forming a first Au catalyst layer in a method of a comparative example.

FIG. 7 is a cross-sectional view schematically illustrating a structure obtained by etching using a first Au catalyst in the method of the comparative example.

FIG. 8 is a cross-sectional view schematically illustrating a structure obtained by forming a second Au catalyst layer in the method of the comparative example.

FIG. 9 is a cross-sectional view schematically illustrating a structure obtained by etching using a second Au catalyst in the method of the comparative example.

FIG. 10 is an electron micrograph illustrating a vicinity of an upper end of a trench processed by the method of the comparative example.

### DETAILED DESCRIPTION

In general, according to one embodiment, an etching method is provided. The etching method includes: forming a layer containing a first metal catalyst at a surface containing a semiconductor; first etching using the first metal catalyst; forming a layer containing a second metal catalyst having a larger diffusion coefficient than that of the first metal catalyst at the layer containing the first metal catalyst; and second etching using the second metal catalyst.

Hereinafter, embodiments will be described in detail with reference to the accompanying drawings. Constituents which achieve the same or similar functions are denoted by the same reference numerals throughout the drawings, and repetitive descriptions will be omitted.

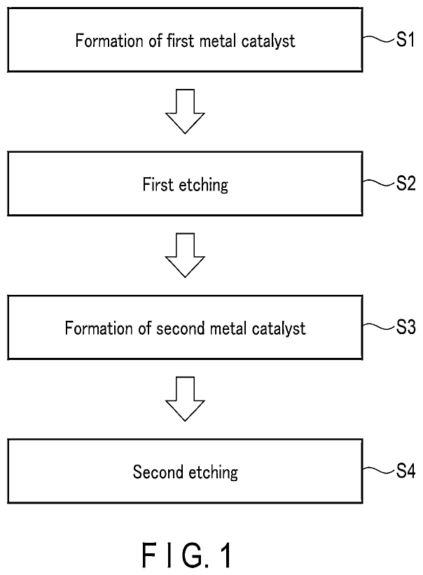

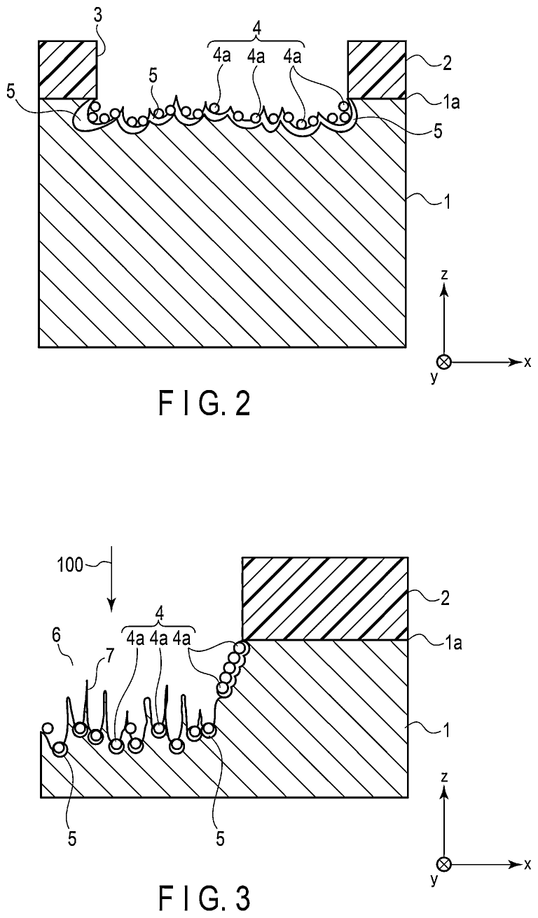

FIG. 1 is a flowchart illustrating a flow of steps in an etching method according to an embodiment. As illustrated in FIG. 1, the etching method of the embodiment includes formation of a first metal catalyst (step S1), first etching (step S2), formation of a second metal catalyst (step S3), and second etching (step S4). Hereinafter, the respective steps will be described with reference to FIGS. 2 to 5. Each of the figures is illustrated on a premise that a surface to be etched is parallel to a plane defined by an x-axis direction and a y-axis direction. The surface to be processed may be, for example, a main surface of a substrate. It is assumed that processing by etching progresses in a direction 100 along a z-axis direction from the surface to be processed. The x axis, the y axis, and the z axis cross each other perpendicularly.

### (Step S1)

A first metal catalyst is formed at a surface containing a semiconductor.

The semiconductor is, for example, silicon (Si); germanium (Ge); a semiconductor formed of a compound containing a group III element and a group V element, such as gallium arsenide (GaAs) or gallium nitride (GaN); and silicon carbide (SiC). According to an example, the surface containing a semiconductor is a surface containing silicon. The term “group” used herein is a “group” in the short-form periodic table.

The surface containing a semiconductor may be, for example, a semiconductor substrate. The semiconductor substrate is, for example, a semiconductor wafer. The semiconductor wafer may be doped with an impurity, and may be formed with a semiconductor element such as a transistor or a diode. Further, a main surface of the semiconductor wafer may be parallel to any crystal plane of the semiconductor. A usable semiconductor wafer is, for example, a silicon wafer whose main surface is a (100) plane or a silicon wafer whose main surface is a (110) plane.

An example of a structure obtained in step S1 is illustrated in FIG. 2. A mask layer 2 is provided on at least a part of a surface of a substrate 1 containing a semiconductor, for example, one main surface 1a of the substrate 1. The main surface 1a of the substrate 1 is, for example, a surface parallel to a plane defined by an x-axis direction and a y-axis direction. The semiconductor includes, for example, Si. The substrate 1 may have any shape. Here, as an example, the substrate 1 is a single-crystal silicon wafer. A plane orientation of the single-crystal silicon wafer is not particularly limited. In FIG. 2, a silicon wafer whose main surface 1a is a (100) plane is used as the substrate 1. As the substrate 1, a silicon wafer whose main surface is a (110) plane can also be used.

The mask layer 2 has one or more openings 3. A shape of the opening 3 is not particularly limited. The opening 3 has, for example, a groove shape extending in the y-axis direction and penetrating in the z-axis direction. In addition, a number of the openings 3 is not limited, and can be one or more. The mask layer 2 can prevent contact of a metal catalyst with a region of the surface of the substrate 1 covered with the mask layer 2. The mask layer 2 may be, for example, a resist.

Examples of the material of the mask layer 2 include organic materials such as polyimide, fluororesin, phenol resin, acrylic resin, and novolak resin, and inorganic materials such as silicon oxide and silicon nitride.

The mask layer 2 may be formed by, for example, an existing semiconductor process. The mask layer 2 made of an organic material may be formed by, for example, photolithography. The mask layer 2 made of an inorganic material may be formed by, for example, formation of an inorganic material layer by a vapor deposition method, formation of a mask by photolithography, and patterning of the inorganic material layer by etching. Alternatively, the mask layer 2 made of an inorganic material may be formed by oxidation or nitration of the surface region of the substrate 1, formation of a mask by photolithography, and patterning of an oxide or nitride layer by etching. The mask layer 2 may be omitted.

A layer 4 containing the first metal catalyst (hereinafter, referred to as a first metal catalyst layer 4) is provided on a portion of the main surface 1a of the substrate 1 in the position of the opening 3 of the mask layer 2. In other words, the first metal catalyst layer 4 is provided on the portion of the main surface 1a of the substrate 1 not covered by the mask layer 2. After the mask layer 2 is provided on the main surface 1a of the substrate 1, the first metal catalyst layer 4 can be formed on a portion of the main surface 1a positioned in the opening 3 of the mask layer 2 by, for example, an electroless plating method or a sputtering method.

The first metal catalyst layer 4 contains, for example, first metal catalyst particles 4a. As an example of the first metal catalyst layer 4 containing the first metal catalyst particles 4a, a layer structure formed by depositing the first metal catalyst particles 4a can be indicated. The first metal catalyst layer 4 is not limited to those containing the first metal catalyst particles 4a. For example, the first metal catalyst layer 4 may include a first metal catalyst formed in a film shape. In this case, the first metal catalyst layer 4 can be formed by, for example, a sputtering method.

The first metal catalyst layer 4 containing the first metal catalyst particles 4a can be formed by, for example, displacement plating which is an example of electroless plating. A displacement plating solution is, for example, a mixed solution of a salt of the first metal catalyst and hydrofluoric acid. Hydrofluoric acid can remove a native oxide film on the surface of the substrate. By adjusting a concentration of a first metal catalyst salt or a concentration of hydrofluoric acid in the displacement plating solution, a size of the first metal catalyst particles and a density of the first metal catalyst layer can be set within predetermined ranges. For example, if the concentration of the first metal catalyst salt or the concentration of hydrofluoric acid is lowered, first metal catalyst particles having a nanometer size can be formed, and a catalyst layer in which the first metal catalyst particles are distributed at a high number density can be obtained. In addition, if the concentration of the first metal catalyst salt or the concentration of hydrofluoric acid is increased, the first metal catalyst particles are bonded, so that a catalyst layer in which large first metal catalyst particles are distributed at a low number density can be obtained.

The first metal catalyst has a smaller diffusion coefficient than that of a second metal catalyst. Therefore, the first metal catalyst is less likely to diffuse into the substrate 1 than the second metal catalyst. Therefore, it is possible to suppress diffusion of the first metal catalyst into the substrate 1, thereby suppressing generation of a metal catalyst diffusion layer 5 in a substrate portion located near the first metal catalyst layer 4.

As the diffusion coefficient, a coefficient of diffusion into a semiconductor component (for example, Si) constituting the substrate can be used. The diffusion coefficient can be calculated using an equation of Fick's second law. An example method for calculating the diffusion coefficient is described in Proposal of a New Diffusion Equation Related to Solid State Reaction by Goro Yamaguchi et al., Journal of the Ceramic Association, Japan 78 [9] 1970, pages 293 to 298.

The first metal catalyst can contain at least one selected from the group consisting of Ag, Pt, and Pd. A preferred first metal catalyst is at least one of Pt or Pd. According to an example, the diffusion coefficient of Ag into Si is 3.8×10⁻¹³ (m²/s) or more and 4.6×10⁻⁹ (m²/s) or less at 1400 K. According to an example, the diffusion coefficient of Pt into Si is 7.7×10⁻¹⁵ (m²/s) or more and 1.8×10⁻¹⁰ (m²/s) or less at 1400 K. According to an example, the diffusion coefficient of Pd into Si is 4.8×10⁻⁹ (m²/s) at 1400 K. For the diffusion coefficient of each of the elements, the diffusion database (Kakusan) DICE by National Institute for Materials Science (nims.go.) is referred to. A value of the diffusion coefficient may vary depending on conditions of a Si wafer (for example, resistivity, difference between n-type and p-type, crystal orientation, and the like), and thus may have a range. The resistivity of the Si wafer as an example of the substrate is 1 to 5 Ω·cm as an example. In addition, the first etching is performed, for example, near normal temperature. In this case, as the diffusion coefficient of Ag into Si, 3.8×10⁻¹³ (m²/s) at 1400 K can be used. Also, as the diffusion coefficient of Pt into Si, 7.7×10⁻¹⁵ (m²/s) at 1400 K can be used.

### (Step S2)

In the first etching, etching is performed using the first metal catalyst. The etching is performed by, for example, a metal-assisted etching (also called metal-assisted chemical etching (MacEtch)) method. According to the metal-assisted etching using the first metal catalyst, etching proceeds toward a lower side or directly below of the first metal catalyst, and a recess having a depth in the z-axis direction can be formed.

An example of step S2 will be described with reference to FIG. 3.

The substrate 1 provided with the first metal catalyst is etched with an etching agent. For example, the substrate 1 is immersed in the liquid etching agent to bring the liquid etching agent into contact with the substrate 1. Details of the etching agent (hereinafter, referred to as a first etching agent) will be described below.

The first etching agent contains an oxidizer and hydrogen fluoride (hydrofluoric acid). A specific example of the first etching agent is an aqueous solution containing an oxidizer and hydrogen fluoride.

The oxidizer can be selected from, for example, hydrogen peroxide, nitric acid, AgNO₃, KAuCl₄, HAuCl₄, K₂PtCl₆, H₂PtCl₆, Fe(NO₃)₃, Ni(NO₃)₂, Mg(NO₃)₂, Na₂S₂O₈, K₂S₂O₈, KMnO₄ and K₂Cr₂O₇. Hydrogen peroxide is preferred as the oxidizer because it does not produce a harmful byproduct.

A concentration of hydrogen fluoride (hydrofluoric acid) in the first etching agent can be 3.5 mol/L or more and 4.5 mol/L or less. A concentration of hydrogen peroxide in the first etching agent can be 0.3 mol/L or more and 0.8 mol/L or less. At least one of the concentration of hydrogen fluoride (hydrofluoric acid) or the concentration of hydrogen peroxide is set within the above range, so that a speed of the first etching can be made slow. Therefore, it is easy to obtain a recess shape reflecting the distribution of the first metal catalyst. For example, the etching hardly proceeds in a portion where the first metal catalyst is few or is not present, and thus a needle-shaped protrusion can be partially provided at an inner surface of the recess. Both the concentration of hydrogen fluoride (hydrofluoric acid) and the concentration of hydrogen peroxide are set within the above ranges, so that it is easier to partially provide the needle-shaped protrusion at the inner surface of the recess.

The first etching agent may further contain a buffer. The buffer contains, for example, at least one of ammonium fluoride or ammonia. According to an example, the buffer is ammonium fluoride. According to another example, the buffer is a mixture of ammonium fluoride and ammonia.

The first etching agent may further contain any other component such as water.

As described above, according to MacEtch using the first metal catalyst, the material of the substrate 1, here, silicon is oxidized only in a region of the substrate 1 close to the first metal catalyst particles 4a. The resulting oxide is dissolved and removed by hydrofluoric acid. Therefore, only the portion close to the first metal catalyst particles 4a is selectively etched.

The layer 4 containing the first metal catalyst particles 4a moves toward the other main surface (hereinafter, referred to as a second surface) of the substrate 1 with the progress of etching, where etching similar to the above is performed. As a result, as illustrated in FIG. 3, etching proceeds in a direction perpendicular to the main surface 1a (first surface) from the main surface 1a (first surface) toward the second surface, so that a recess 6 is formed.

However, since the layer 4 containing the first metal catalyst particles 4a has gaps between some of the first metal catalyst particles 4a, etching hardly proceeds at positions corresponding to these gaps. As a result, as illustrated in FIG. 3, needle-shaped protrusions 7 each extending in a direction intersecting the main surface 1a (first surface), for example, a depth direction of the recess 6 along the z-axis direction are generated as etching residues at the inner surface of a bottom portion of the recess 6. Note that the needle-shaped protrusions 7 may not be provided. In this case, the first metal catalyst layer 4 can be formed by a sputtering method.

In a case where the recess 6 is formed by the first etching, the first metal catalyst remains near an opening end of the recess 6. The remaining first metal catalyst is hardly diffused in the substrate portion near the opening end of the recess 6, so that the generation of the metal catalyst diffusion layer 5 can be suppressed.

As described above, a substrate having a surface containing a semiconductor and provided with a recess at the surface is obtained.

The substrate after the first etching is separated from the first etching agent by, for example, pulling it up from the first etching agent. Thereafter, the substrate may be washed with water.

In FIG. 3, a method for forming the needle-shaped protrusions 7 is illustrated, but the protrusions 7 may have another shape. For example, the protrusions 7 each have a flat plate shape, and may be arranged in a thickness direction so as to be separated from each other.

### (Step S3)

A layer containing a second metal catalyst having a larger diffusion coefficient than that of the first metal catalyst (hereinafter, referred to as a second metal catalyst layer) is formed at a layer containing the first metal catalyst (hereinafter, referred to as a first metal catalyst layer).

The second metal catalyst layer may be deposited (for example, precipitated) on the entire first metal catalyst layer, or may be deposited (for example, precipitated) on a part of the first metal catalyst layer. Further, the second metal catalyst layer is desirably deposited on the first metal catalyst layer, but may be formed directly on a part of the surface containing a semiconductor.

The layer containing the second metal catalyst is formed by, for example, an electroless plating method or a sputtering method.

The second metal catalyst has a larger diffusion coefficient than that of the first metal catalyst. As the diffusion coefficient, a coefficient of diffusion into a semiconductor component (for example, Si) constituting the substrate can be used, similarly to the first metal catalyst. As a method for calculating the diffusion coefficient, a method similar to that described for the first metal catalyst can be used.

The second metal catalyst can contain Au. In addition, the second etching is performed, for example, near normal temperature. According to an example, the diffusion coefficient of Au into Si is 3.0×10⁻¹² (m²/s) or more and 2.0×10⁻⁷ (m²/s) or less at 1400 K. For this value, the diffusion database (Kakusan) DICE by National Institute for Materials Science (nims.go.) is referred to. For example, in a case where a Si wafer having a resistivity of 1 to 5 Ω·cm is used as the substrate, 3.0×10⁻¹² (m²/s) at 1400 K can be used as the diffusion coefficient of Au into Si.

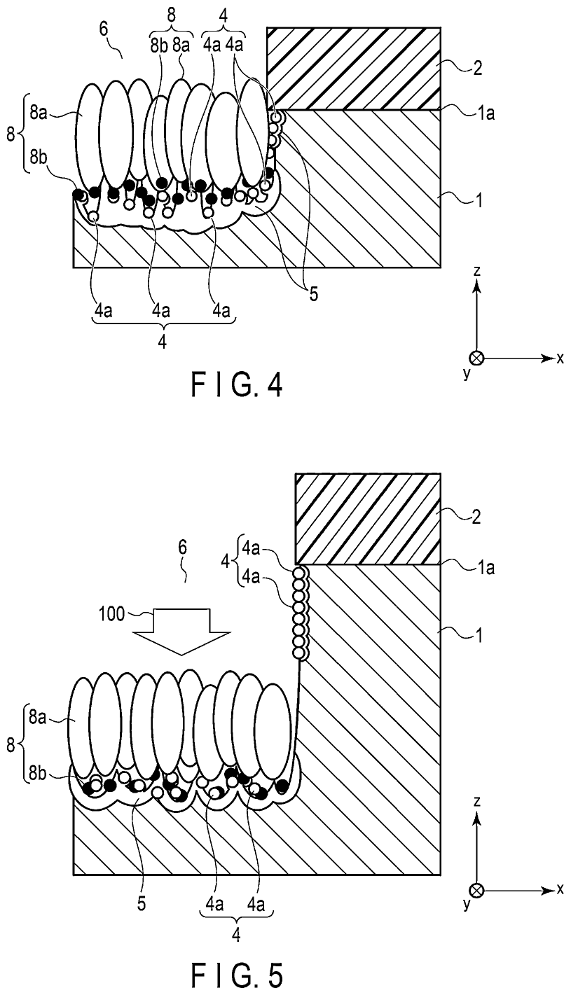

An example in which the second metal catalyst is formed by displacement plating as an example of electroless plating will be described with reference to FIG. 4. The recess 6 having a depth in the z-axis direction is formed in the substrate 1 after the first etching. The first metal catalyst layer 4 containing the first metal catalyst particles 4a exists on a bottom inner surface and a side wall of the recess 6. In the first metal catalyst layer 4, gaps are present between some of the first metal catalyst particles 4a. One or more (in the case of FIG. 4, a plurality of) needle-shaped protrusions 7 are formed at locations corresponding to the gaps between the first metal catalyst particles 4a at the bottom inner surface of the recess 6. In a case where the second metal catalyst is formed by displacement plating, the displacement plating proceeds almost entirely since the protrusions 7 have a needle shape. Therefore, corresponding to the shape of the protrusions 7, the second metal catalyst can be precipitated in a particulate form extending in a direction intersecting the main surface (first surface). That is, this displacement plating provides a second metal catalyst layer 8 containing second metal catalyst particles 8a having a shape extending in the depth direction along the z-axis direction of the recess 6. The second metal catalyst layer 8 also contains granular second metal catalyst particles 8b. The second metal catalyst layer 8 is in contact with the protrusions 7. In addition, since there are gaps between the first metal catalyst particles 4a of the first metal catalyst layer 4, a part of the second metal catalyst layer 8 can be in direct contact with the inner surface of the recess 6. As a result, the second metal catalyst of the second metal catalyst layer 8 diffuses into the substrate 1 through the inner surface of the recess 6 to increase the diffusion layer 5 of the metal catalyst. On the other hand, the first metal catalyst layer 4 provided on the side wall of the recess 6 inhibits formation of the second metal catalyst layer 8 on the side wall of the recess 6. Therefore, it is possible to suppress adhesion of the second metal catalyst layer 8 to the side wall defining the recess 6, particularly to the vicinity of the upper end of the side wall.

The displacement plating solution used in displacement plating is, for example, a mixed solution of hydrofluoric acid, and one of an aqueous solution of tetrachloroauric (III) acid, an aqueous solution of gold sulfite, or an aqueous solution of potassium gold cyanide (I). Hydrofluoric acid can remove a native oxide film on the surface of the substrate.

All of the second metal catalyst particles may have a shape extending in the depth direction of the recess, but the second metal catalyst particles may include particles having this shape and particles having a granular shape. The second metal catalyst layer may contain a film-shaped second metal catalyst. In this case, the second metal catalyst layer can be formed by, for example, a sputtering method.

### (Step S4)

Second etching using a second metal catalyst is performed.

The etching is performed by, for example, a metal-assisted etching (MacEtch) method. According to the metal-assisted etching using the second metal catalyst, etching proceeds toward a lower side or directly below of the second metal catalyst, and a recess having a depth in the z-axis direction can be formed.

An example of step S4 will be described with reference to FIG. 5.

The substrate 1 provided with the second metal catalyst is etched with an etching agent. For example, the substrate 1 is immersed in the liquid etching agent to bring the liquid etching agent into contact with the substrate 1. Details of the etching agent (hereinafter, referred to as a second etching agent) will be described below.

The second etching agent contains an oxidizer and hydrogen fluoride (hydrofluoric acid). A specific example of the second etching agent is an aqueous solution containing an oxidizer and hydrogen fluoride.

Examples of the oxidizer include the same ones as those described for the first etching agent. Hydrogen peroxide is preferred as the oxidizer because it does not produce a harmful byproduct.

A concentration of hydrogen fluoride (hydrofluoric acid) in the second etching agent is desirably higher than the concentration of hydrogen fluoride (hydrofluoric acid) in the first etching agent. Specifically, the concentration of hydrogen fluoride in the second etching agent can be 6.5 mol/L or more and 8.0 mol/L or less. A concentration of hydrogen peroxide in the second etching agent is desirably higher than the concentration of hydrogen peroxide in the first etching agent. Specifically, the concentration of hydrogen peroxide in the second etching agent can be 1.5 mol/L or more and 2.5 mol/L or less. At least one of the concentration of hydrogen fluoride (hydrofluoric acid) or the concentration of hydrogen peroxide is set within the above range, so that a speed of the second etching can be increased. Therefore, a recess having a high aspect ratio can be processed with high productivity.

The second etching agent may further contain a buffer. Examples of the buffer include the same ones as those described for the first etching agent.

The second etching agent may further contain any other component such as water.

According to MacEtch using the second metal catalyst described above, the material of the substrate 1, here, silicon is oxidized only in a region of the recess 6 in the substrate 1 close to the second metal catalyst particles 8a and 8b. The resulting oxide is dissolved and removed by hydrofluoric acid. Therefore, only the portion close to the second metal catalyst particles 8a and 8b is selectively etched. Since the second metal catalyst particles 8a have a shape extending in the depth direction of the recess 6, a substrate portion located immediately below the second metal catalyst layer 8 can be selectively etched. Therefore, it is possible to form a recess 6 with a high aspect ratio having a depth direction in a direction intersecting (for example, perpendicular to) the main surface 1a of the substrate 1.

In addition, since the first metal catalyst layer 4 exists near the upper end of the side wall defining the recess 6, attachment of the second metal catalyst layer 8 is suppressed. Therefore, the metal catalyst diffused in the substrate portion near the upper end of the side wall is mainly the first metal catalyst. Since the first metal catalyst has a smaller diffusion coefficient than that of the second metal catalyst, it is possible to suppress dissolution of a semiconductor (for example, Si) near the upper end of the side wall. As a result, it is possible to reduce processing defects in which the vicinity of the upper end of the side wall defining the recess 6 becomes porous. Therefore, a recess having a high aspect ratio can be processed with high productivity.

The substrate after the second etching is separated from the second etching agent by, for example, pulling it up from the second etching agent. Thereafter, the substrate may be washed. The mask layer can also be removed as necessary.

FIGS. 2 to 5 illustrate a simplified structure for easy understanding. Actually, in the plating treatment for generating the first metal catalyst particles 4a or the second metal catalyst particles 8a and 8b, the catalyst particles may be connected to each other. Therefore, the first metal catalyst layer 4 and the second metal catalyst layer 8 do not necessarily have a structure in which the two layers can be clearly distinguished from each other as illustrated in the drawings.

### EXAMPLES

Hereinafter, Examples will be described.

### Example 1

First, a silicon wafer whose main surface is a (100) plane was prepared. Next, a mask layer having an opening was formed on the main surface of this silicon wafer. The mask layer was formed by photolithography using a photoresist.

Next, an aqueous solution of silver nitrate and hydrofluoric acid were mixed to prepare a displacement plating solution. This displacement plating solution had a silver nitrate concentration of 0.001 mol/L and a hydrogen fluoride concentration of 1 mol/L.

The temperature of the displacement plating solution was adjusted to 20° C., and the silicon wafer formed with the mask layer was immersed therein for 180 seconds. As described above, a first metal catalyst layer containing silver particles as the first metal catalyst was formed on the silicon wafer in the position of the opening of the mask layer.

Next, hydrofluoric acid and hydrogen peroxide were mixed to prepare a first etching agent. The first etching agent was an aqueous solution having a hydrogen fluoride concentration of 3.8 mol/L and a hydrogen peroxide concentration of 0.5 mol/L. The temperature of the first etching agent was adjusted to 20° C., and the substrate formed with the mask layer and the first metal catalyst layer was immersed for 30 seconds for etching (first etching). As a result, a trench was formed, and needle-shaped Si was formed in the trench. The needle-shaped Si was present mainly at the bottom inner surface in the trench. In addition, the first metal catalyst layer was present from the bottom inner surface of the trench to the vicinity of the upper end of the wall surface of the trench.

A displacement plating solution for forming the second metal catalyst layer was prepared by mixing an aqueous solution of tetrachloroauric (III) acid and hydrofluoric acid. This displacement plating solution had a tetrachloroauric (III) acid concentration of 0.003 mmol/L and a hydrogen fluoride concentration of 1 mol/L. A second metal catalyst layer was formed by adjusting the temperature of the displacement plating solution to 20° C. and immersing the substrate formed with the mask layer, the first metal catalyst layer, and the needle-shaped Si in the displacement plating solution for 3 minutes. The second metal catalyst layer contained gold particles as a second metal catalyst. Some of the gold particles had a columnar shape and extended in the depth direction of the trench. Some of the other gold particles were granular.

Next, hydrofluoric acid and hydrogen peroxide were mixed to prepare a second etching agent. The second etching agent was an aqueous solution having a hydrogen fluoride concentration of 3.8 mol/L and a hydrogen peroxide concentration of 0.5 mol/L. The temperature of the second etching agent was adjusted to 20° C., and the substrate formed with the mask layer, the second metal catalyst layer, and the needle-shaped Si was immersed for 70 seconds for etching (second etching). As a result, a trench having a predetermined depth and predetermined aspect ratio was formed without generating a porous region near the upper end of the wall surface of the trench.

### Example 2

A trench having a predetermined depth and predetermined aspect ratio was formed without generating a porous region in the vicinity of the upper end of the wall surface of the trench in the same manner as in Example 1 except that the first metal catalyst layer was formed by the following method.

A hexachloroplatinic (IV) acid solution and hydrofluoric acid were mixed to prepare a displacement plating solution. This displacement plating solution had a hexachloroplatinic (IV) acid concentration of 0.0005 mol/L and a hydrogen fluoride concentration of 1 mol/L.

The temperature of the displacement plating solution was adjusted to 20° C., and the silicon wafer formed with the mask layer was immersed therein for 120 seconds. As described above, a first metal catalyst layer containing platinum particles as the first metal catalyst was formed on the silicon wafer in the position of the opening of the mask layer.

### Example 3

A trench having a predetermined depth and predetermined aspect ratio was formed without generating a porous region in the vicinity of the upper end of the wall surface of the trench in the same manner as in Example 1 except that the first metal catalyst layer was formed by the following method.

An aqueous solution of palladium (II) nitrate and hydrofluoric acid were mixed to prepare a displacement plating solution. This displacement plating solution had a palladium (II) nitrate concentration of 0.0005 mol/L and a hydrogen fluoride concentration of 1 mol/L.

The temperature of the displacement plating solution was adjusted to 20° C., and the silicon wafer formed with the mask layer was immersed therein for 180 seconds. As described above, a first metal catalyst layer containing palladium particles as the first metal catalyst was formed on the silicon wafer in the position of the opening of the mask layer.

### COMPARATIVE EXAMPLE

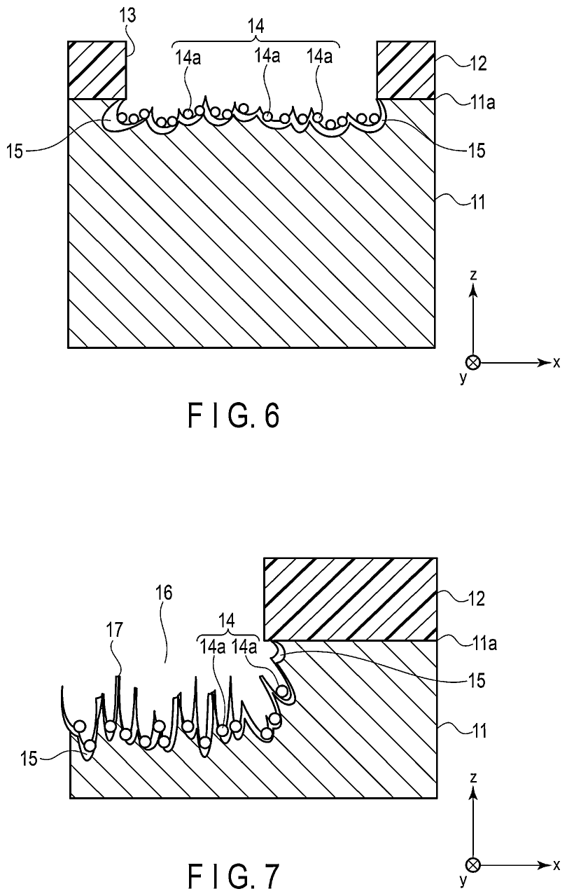

A comparative example will be described with reference to FIGS. 6 to 10.

First, a silicon wafer 11 whose main surface 11a is a (100) plane was prepared. Next, a mask layer 12 having an opening 13 was formed on the main surface 11a of this silicon wafer. The mask layer 12 was formed by photolithography using a photoresist.

An aqueous solution of tetrachloroauric (III) acid and hydrofluoric acid were mixed to prepare a displacement plating solution. This displacement plating solution had a tetrachloroauric (III) acid concentration of 0.0005 mmol/L and a hydrogen fluoride concentration of 1 mol/L. A first Au catalyst layer 14 containing first Au particles 14a was formed by adjusting the temperature of the displacement plating solution to 20° C. and immersing a substrate 11 formed with the mask layer 12 for 90 seconds. A structure formed by this displacement plating is illustrated in FIG. 6. As illustrated in FIG. 6, an Au diffusion layer 15 was formed in a substrate portion located near the first Au particles 14a.

Next, hydrofluoric acid and hydrogen peroxide were mixed to prepare an etching agent. The etching agent had a hydrogen fluoride concentration of 3.8 mol/L and a hydrogen peroxide concentration of 0.5 mol/L. The temperature of the etching agent was adjusted to 20° C., and the substrate 11 formed with the mask layer 12 and the first Au catalyst layer 14 was immersed for 75 seconds for etching. As a result, as illustrated in FIG. 7, a trench 16 was formed, and needle-shaped Si 17 was formed at the bottom inner surface of the trench 16. The Au diffusion layer 15 was present on the entire inner surface of the trench 16.

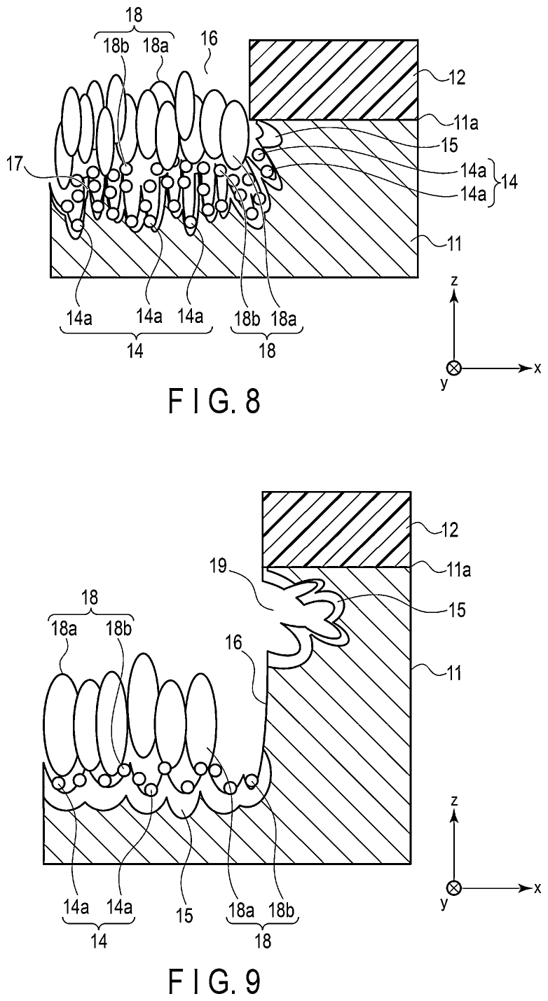

A displacement plating solution for forming the second Au catalyst layer 18 containing second Au particles 18a and 18b was prepared by mixing an aqueous solution of tetrachloroauric (III) acid and hydrofluoric acid. This displacement plating solution had a tetrachloroauric (III) acid concentration of 0.003 mmol/L and a hydrogen fluoride concentration of 1 mol/L. The second Au catalyst layer 18 was formed by adjusting the temperature of the displacement plating solution to 20° C. and immersing the substrate formed with the mask layer, the first metal catalyst layer, and the needle-shaped Si in the displacement plating solution for 3 minutes. A structure obtained by this displacement plating is illustrated in FIG. 8. As illustrated in FIG. 8, the second Au particles 18a had a columnar shape extending in the depth direction of the trench 16. The second Au particles 18b had a granular shape. The Au diffusion layer 15 was present on the entire inner surface of the trench 16.

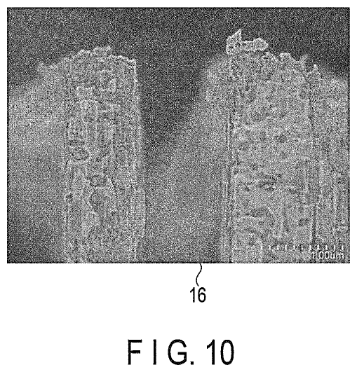

Next, hydrofluoric acid and hydrogen peroxide were mixed to prepare an etching agent. The etching agent had a hydrogen fluoride concentration of 7.5 mol/L and a hydrogen peroxide concentration of 2 mol/L. The temperature of the etching agent was adjusted to 20° C., and the substrate formed with the mask layer 12, the second Au catalyst layer 18, and the needle-shaped Si 17 was immersed for 70 seconds for etching. As illustrated in FIG. 9, the obtained trench 16 had a porous shape 19 near the upper end of the wall surface. FIG. 10 shows an enlarged view of a scanning electron micrograph (SEM photograph) of the vicinity of the upper end of the wall surface of the trench 16 obtained by the method of the comparative example. As also illustrated in FIG. 10, the trench 16 has a predetermined aspect ratio, but a depression or small pore is generated near the upper end of the wall surface of the trench 16. It is presumed that Si was dissolved by the action of the Au diffusion layer 15 present near the upper end of the wall surface of the trench 16.

The etching method of at least one embodiment or example described above includes: forming a layer containing a first metal catalyst at a surface containing a semiconductor; first etching using the first metal catalyst; forming a layer containing a second metal catalyst having a larger diffusion coefficient than that of the first metal catalyst at the layer containing the first metal catalyst; and second etching using the second metal catalyst. This method can suppress the occurrence of a processing defect at a wall surface defining a recess, for example, near an upper end of a wall surface. Therefore, it is easy to process a recess having a high aspect ratio.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An etching method comprising:
forming a layer comprising a first metal catalyst at a surface comprising a semiconductor;
first etching using the first metal catalyst;
forming a layer comprising a second metal catalyst having a larger diffusion coefficient than that of the first metal catalyst at the layer comprising the first metal catalyst; and
second etching using the second metal catalyst.

2. The etching method according to claim 1, wherein the first etching and the second etching are metal-assisted etching.

3. The etching method according to claim 1, wherein the first metal catalyst comprises at least one selected from the group consisting of Ag, Pt, and Pd.

4. The etching method according to claim 1, wherein the second metal catalyst comprises Au.

5. The etching method according to claim 1, wherein the first metal catalyst comprises at least one selected from the group consisting of Ag, Pt, and Pd, and the second metal catalyst comprises Au.

6. The etching method according to claim 1, wherein at least one of the layer comprising the first metal catalyst or the layer comprising the second metal catalyst is formed by an electroless plating method or a sputtering method.

7. The etching method according to claim 1, wherein the semiconductor comprises Si.
